(19) United States
(12) Patent Application Publication
(10) Pub. No.: US 2019/0051858 A1
(43) Pub. Date: Feb. 14, 2019

(54) DISPLAY DEVICE

(71) Applicant: Japan Display Inc., Minato-ku (JP)

(72) Inventors: Yasushi TOMIOKA, Tokyo (JP); Hajime YAMAGUCHI, Tokyo (JP); Akio MURAYAMA, Tokyo (JP)

(73) Assignee: Japan Display Inc., Minato-ku (JP)

(21) Appl. No.: 16/100,751

(22) Filed: Aug. 10, 2018

(30) Foreign Application Priority Data
Aug. 10, 2017 (JP) 2017-155749
May 30, 2018 (JP) 2018-103359

(51) Int. Cl. H01L 51/52; G02F 1/1339; G02F 1/1333; H01L 27/32

(52) U.S. Cl. CPC H01L 51/5246; G02F 1/1339; G02F 1/133345; H01L 51/0097; H01L 27/3258; G02F 2201/121; G02F 2201/123; H01L 27/3276

(57) ABSTRACT

According to one embodiment, a display device includes a display panel including a first area including a display area, a second area including a terminal portion and a third area located between the first area and the second area and a cover member adhered to the first area via an adhesive layer, and the display panel is bent in the third area so that the first area and the second area oppose each other on a side opposite to the cover member, and the third area is adhered to the cover member by a first resin.

### CROSS-REFERENCE TO RELATED APPLICATIONS

This application is based upon and claims the benefit of priority from Japanese Patent Applications No. 2017-155749, filed Aug. 10, 2017; and No. 2018-103359, filed May 30, 2018, the entire contents of all of which are incorporated herein by reference.

### FIELD

Embodiments described herein relate generally to a display device.

### BACKGROUND

In recent years, flexible display devices adopting a resin substrate have been developed. As to the flexible display devices, there is a demand of reducing the area of the frame portion on an outer side of the display area. For example, such a method can be considered that a terminal side end is bent by about 180 degrees so that the terminal portion is located in a rear surface of the display panel, thereby reducing the area of the frame portion. Here, if a gap is created in an inner side the bent portion, and a force is applied in a direction to compresses the gap, a wiring line arranged at the bent portion may be broken. Under these circumstances, a technique for of eliminating such a gap inside the bent portion has been proposed to suppress the breaking of wiring lines.

### BRIEF DESCRIPTION OF THE DRAWINGS

FIG. 1 is a perspective view showing a configuration of a display device according to an embodiment.

FIG. 2 is a cross-sectional view of a display area of the display device shown in FIG. 1.

FIG. 3 is a cross-sectional view of a non-display area of the display device of FIG. 1.

FIG. 4 is a plan view showing a display panel PNL according to this embodiment, also illustrating positions of a first support substrate and a second support substrate with relative to each other, etc.

FIG. 5 is a cross section showing a state where a bend area of the display panel shown in FIG. 3 has been bent.

FIG. 6 is a diagram showing a first example of this embodiment.

FIG. 7 is a diagram showing a second example of this embodiment.

FIG. 8 is a diagram showing a third example of this embodiment.

FIG. 9 is a diagram showing a fourth example of this embodiment.

FIG. 10 is a diagram showing a fifth example of this embodiment.

FIG. 11 is a diagram showing a sixth example of this embodiment.

FIG. 12 is a diagram showing a seventh example of this embodiment.

FIG. 13 is a diagram showing an eighth example of this embodiment.

FIG. 14 is a plan view of the display device shown in FIG. 13 from a cover member side.

FIG. 15 is a diagram showing a ninth example of this embodiment.

FIG. 16 is a diagram showing a tenth example of this embodiment.

FIG. 17 is a cross-sectional view of the display device of FIG. 15 taken along line I-I′.

FIG. 18 is a diagram showing an eleventh example of this embodiment.

FIG. 19 is a diagram showing a twelfth example of this embodiment.

FIG. 20 is a diagram showing a thirteenth example of this embodiment.

FIG. 21 is a diagram showing a fourteenth example of this embodiment.

FIG. 22 is a graph showing the change in the flexural rigidity of a bend area with respect to a film thickness of a protective member.

FIG. 23 is graph showing a flexural rigidity ratio between a first position and a second position, with respect to the film thickness of the protective member, and the film thickness of the support substrate.

FIG. 24 is a diagram showing a fifteenth example of this embodiment.

FIG. 25 is a diagram showing a sixteenth example of this embodiment.

FIG. 26 is graph showing a flexural rigidity ratio between a first position and a second position, with respect to the film thickness of the protective member, and the film thickness of the support substrate in the sixteenth example shown in FIG. 25.

### DETAILED DESCRIPTION

In general, according to one embodiment, a display device comprises a display panel including a first area including a display area, a second area including a terminal portion and a third area located between the first area and the second area and a cover member adhered to the first area via an adhesive layer, and the display panel is bent in the third area so that the first area and the second area oppose each other on a side opposite to the cover member, and the third area is adhered to the cover member by a first resin.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, structural elements which exhibit a function identical or similar to those described in connection with preceding drawings are denoted by like reference numerals, and a detailed description thereof is omitted unless otherwise necessary.

First, a display device according to this embodiment will be described in detail. Further, the embodiment will be described in connection with the case where a display device DSP is an organic electroluminescent (EL) display device.

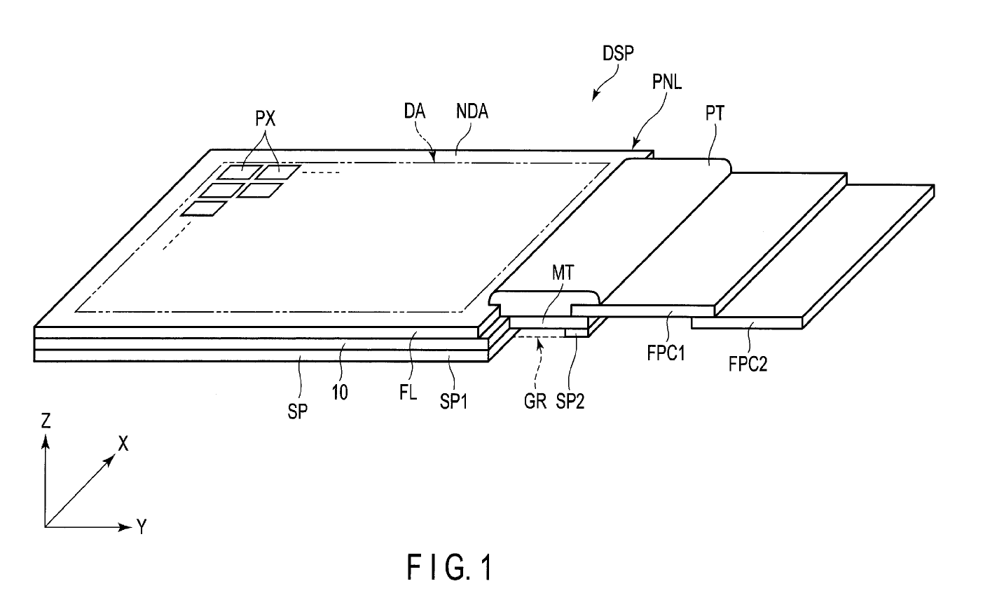

FIG. 1 is a perspective view illustrating a configuration of the display device DSP according to the embodiment. FIG. 1 shows a three-dimensional space defined by a first axis X, a second axis Y perpendicular to the first axis X, and a third axis Z perpendicular to the first axis X and the second axis Y. In the example illustrated, the first direction X, the second direction Y and the third direction Z are orthogonal to each other, but may cross each other at an angle other than 90 degrees.

In this embodiment, a direction towards a distal end of an arrow of the third direction Z is defined as up, and a direction opposite to the direction towards the distal end of the arrow of the third direction Z is defined as down. Moreover, such expressions as “a second member on a first member” and “a second member under a first member”, the second member may be in contact with the first member, or may be separated from the first member. In the latter case, a third member may be interposed between the first member and the second member.

As shown in FIG. 1, the display device DSP comprises a display panel PNL, a wiring substrate FPC1, a wiring substrate FPC2 and the like.

The display panel PNL comprises an insulating substrate 10, a film FL, a support substrate SP, a protective member PT and the like. The display panel PNL includes a display area DA which displays images and a non-display area NDA surrounding the display area DA. The display panel PNL includes a plurality of pixels PX in the display area DA. The pixels PX are arranged in a matrix along the first direction X and the second direction Y.

The film FL is disposed on the insulating substrate 10. In the example illustrated, three end portions of the film FL are aligned respectively with three end portions of the insulating substrate 10 along the third direction Z. The length of an end portion of the film FL, which is parallel to the first direction X is substantially equal to the length of an end portion of the insulating substrate 10, which is parallel to the first direction X. Further, the length of an end portion of the film FL, which is parallel to the second direction Y is less than the length of an end portion of the insulating substrate 10, which is parallel to the second direction Y. That is, in an X-Y plane defined by the first direction X and the second direction Y, the area of the film FL is smaller than the area of the insulating substrate 10. Note that as will be described later, a plurality of members are disposed between the insulating substrate 10 and the film FL.

The support substrate SP is attached under the insulating substrate 10. The support substrate SP includes a first support substrate SP1, a second support substrate SP2, and a groove portion GR formed between the first support substrate SP1 and the second support substrate SP2. The first support substrate SP1 overlaps the display area DA along the third direction Z. The groove portion GR and the second support substrate SP2 overlap the non-display area NDA of the insulating substrate 10 along the third direction Z.

The display panel PNL includes a mounting portion MT extending outwards from the region where the film FL is disposed. The protective member PT is disposed on the mounting portion MT. The protective member PT is in contact with the film FL and the wiring substrate FPC1.

In the example illustrated, the wiring substrate FPC1 is mounted on the mounting portion MT in the non-display area NDA. In the example illustrated, the length of an end portion of the wiring substrate FPC1, which is parallel to the first direction X is substantially equal to the length of an end portion of the mounting portion MT, which is parallel to the first direction X. The display panel PNL and the wiring substrate FPC1 are electrically connected to each other. The wiring substrate FPC2 is disposed under the wiring substrate FPC1 and is electrically connected thereto. The wiring substrate FPC2 overlaps a side of the wiring substrate FPC1 opposite to the side where the display panel PNL overlaps. Note that the wiring substrate FPC2 may be disposed on the wiring substrate FPC1.

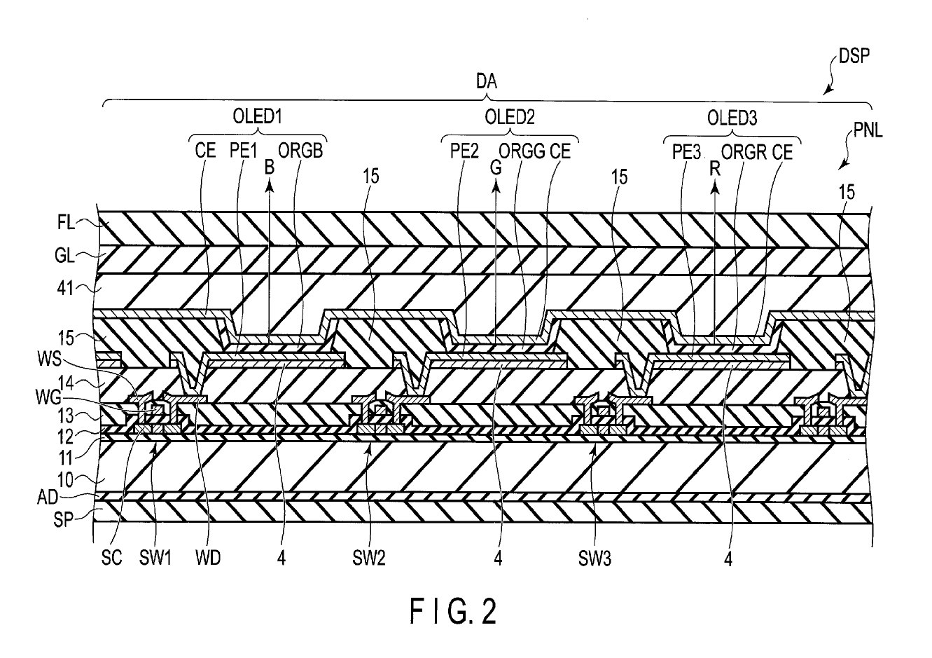

FIG. 2 is a cross-sectional view of the display area DA of the display device DSP of FIG. 1.

As shown in FIG. 2, the display panel PNL comprises an insulating substrate 10, switching elements SW1, SW2 and SW3, a reflective layer 4, organic EL devices OLED1, OLED2 and OLED3, a sealing layer 41, a support substrate SP, an adhesive layer GL, the film FL and the like.

The insulating substrate 10 is formed from, for example, an organic insulating material such as polyimide. The insulating substrate 10 is covered by a first insulating film 11. The insulating substrate 10 may comprise only a single layer formed of an organic insulating material such as polyimide, or a multilayer in which layers formed of an organic insulating material and layers formed of an inorganic insulating material are stacked one on another alternately.

The switching elements SW1, SW2 and SW3 are formed on the first insulating film 11. In the example illustrated, the switching elements SW1, SW2 and SW3 are each of a top-gate transistor; however, they may be of bottom-gate type transistors. Since the switching element SW1, SW2 and SW3 are identical in configuration, the configuration thereof will be described in detail while focusing on the switching element SW1. The switching elements SW1 includes a semiconductor layer SC formed on the first insulating film 11. The semiconductor layer SC is covered by a second insulating film 12. The second insulating film 12 is formed also on the first insulating film 11.

A gate electrode WG of the switching element SW1 is formed on the second insulating film 12 and is located directly above the semiconductor layer SC. The gate electrode WG is covered by a third insulating film 13. Further, the third insulating film 13 is formed also on the second insulating film 12.

The first insulating film 11, second insulating film 12 and third insulating film 13 are formed of, for example, an inorganic material such as a silicon oxide or a silicon nitride.

A source electrode WS and a drain electrode WD of the switching element SW1 are formed on the third insulating film 13. The source electrode WS and the drain electrode WD are electrically connected to the semiconductor layer SC through a contact hole penetrating the second insulating film 12 and the third insulating film 13. The switching element SW1 is covered by a fourth insulating film 14. The fourth insulating film 14 is formed also on the third insulating film 13. The fourth insulating film 14 is formed of, for example, an organic material such as transparent resin.

The reflective layer 4 is formed on the fourth insulating film 14. The reflective layer 4 is formed of a highly reflective metal material such as aluminum or silver. An upper surface of the reflective layer 4 may be a flat surface, or may be an irregular surface with projections and recesses, to impart light scatterability.

The organic EL devices OLED1 to OLED3 are formed on the fourth insulating film 14. That is, the organic EL devices OLED1 to OLED3 are located between the insulating substrate 10 and the film FL. In the example illustrated, the organic EL device OLED1 is electrically connected to the switching element SW1, the organic EL device OLED2 is electrically connected to the switching element SW2, and the organic EL device OLED3 is electrically connected to the switching element SW3. The organic EL devices OLED1 to OLED3 are constituted as top emission types which emit red light, blue light, and green light toward the film FL side, respectively. The organic EL devices OLED1 to OLED3 are all of the same structure. In the illustrated example, the organic EL devices OLED1 to OLED3 are divided into compartments by ribs 15, respectively.

The organic EL device OLED1 comprises a pixel electrode PE1 formed on the reflective layer 4. The pixel electrode PE1 is brought into contact with the drain electrode WD of the switching element SW1 and electrically connected to the switching element SW1. Similarly, the organic EL device OLED2 comprises a pixel electrode PE2 electrically connected to the switching element SW2, and the organic EL device OLED3 comprises a pixel electrode PE3 electrically connected to the switching element SW3. The pixel electrodes PE1, PE2 and PE3 are formed of, for example, a transparent conductive material such as indium tin oxide (ITO) or indium zinc oxide (IZO).

For example, the organic EL device OLED1 comprises an organic emitting layer ORGB which emits blue light, the organic EL device OLED2 comprises an organic emitting layer ORGG which emits green light, and the organic EL device OLED3 comprises an organic emitting layer ORGR which emits red light. The organic emitting layer ORGB is located on the pixel electrode PE1, the organic emitting layer ORGG is located on the pixel electrode PE2, and the organic emitting layer ORGR is located on the pixel electrode PE3. Moreover, the organic EL devices OLED1 to OLED3 comprise a common electrode CE. The common electrode CE is located on the organic light-emitting layers ORGB, ORGG and ORGR. The common electrode CE is located also on the ribs 15. One of the pixel electrode PE and the common electrode CE is a positive electrode, and the other is a negative electrode. The common electrode CE is formed from, for example, a transparent conductive material such as ITO or IZO.

The sealing layer 41 covers the organic EL devices OLED1, OLED2 and OLED3 from an upper side. The sealing layer 41 seals the members disposed between the sealing layer 41 itself and the insulating substrates 10. The sealing layer 41 inhibits the entering of oxygen or moisture into the organic EL devices OLED1, OLED2 and OLED3 to suppress degradation of the organic EL devices OLED1, OLED2 and OLED3. The sealing layer 41 may be formed of a multilayered body of an inorganic film and an organic layer.

The film FL is disposed on the sealing layer 41. The film FL is, for example, a protection film, an optical film or the like, and formed from a transparent material. The film FL is adhered to the sealing layer 41 by the adhesive layer GL. The adhesive layer GL is formed from, for example, any one of an acrylic material, an epoxy material and polyimide.

The support substrate SP is adhered onto a surface of the insulating substrate 10, opposite to a film FL side thereof. The support substrate SP is adhered to the insulating substrate 10 by an adhesive layer AD. A preferable example of the material of the support substrate SP is one that is heat resistive, gas-blocking, moisture-proof, strong, and also inexpensive. The support substrate SP has, for example, such a degree of heat resistance that it does not deteriorate or deform with a process temperature in the process of manufacturing the display device DSP. Further, the support substrate SP has, for example, a higher strength than that of the insulating substrate 10 and functions as a support layer which inhibits the display panel PNL from curving even if no stress is applied from outside. Furthermore, the support substrate SP has, for example, a moisture-proof to inhibit the entering of moisture into the insulating substrate 10, and a gas blocking property to inhibit the entering of a gas, and it functions as a barrier layer. The support substrate SP is, for example, a film formed from polyethylene terephthalate.

In the display device DSP, when the organic EL devices OLED1 to OLED3 emit light, the organic EL device OLED1 emits blue light, the organic EL device OLED2 emits green light, and the organic EL device OLED3 emits red light. Thus, the display device DSP displays images in color.

The pixels PX shown in FIG. 1 are each, for example, a minimum unit which constitutes a color image, and includes the organic EL devices OLED1 to OLED3, described above.

In the configuration example provided above, the organic EL devices OLED1 to OLED3 comprise the organic emitting layer ORGB which emits blue light, the organic emitting layer ORGG which emits green light, and the organic emitting layer ORGR which emits red light, respectively, but the configuration is not limited to this. The organic EL devices OLED1 to OLED3 may comprise a common organic emitting layer. Here, the organic EL devices OLED1 to OLED3 may emit, for example, white light. In such a configuration example, a color filter layer is disposed on the sealing layer 41.

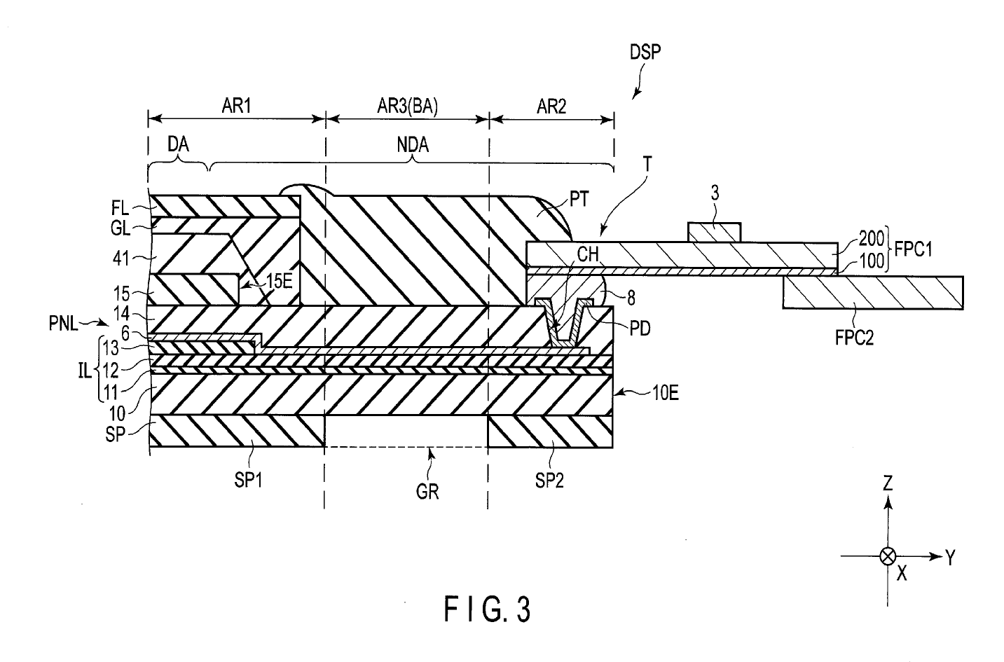

FIG. 3 is a cross-sectional view of the display device DSP shown in FIG. 1, which includes the non-display area NDA.

In the example illustrated, the first insulating film 11 and the second insulating film 12 extend to a position overlapping an end portion 10E of the insulating substrate 10. The third insulating film 13 does not extend to a position overlapping the groove portion GR. The first insulating film 11, the second insulating film 12 and the third insulating film 13 constitute an inorganic insulating film IL.

A signal wiring line 6 is disposed on the second insulating film 12 and the third insulating film 13. The signal wiring line 6 is continuously formed from the display area DA to the non-display area NDA, to extend to a position overlapping a pad PD. The signal wiring line 6 is formed from a multilayer of, for example, titanium/aluminum/titanium. The signal line 6 is equivalent to a power source line or any one of various control lines.

The fourth insulating film 14 covers the signal wiring line 6. The fourth insulating film 14 comprises a contact hole CH penetrating to the signal wiring line 6.

The pad PD is disposed on the fourth insulating film 14 and also in the contact hole CH. The pad PD is electrically connected to the signal wiring line 6 in the contact hole CH. The pad PD is formed in the same processing step as those of the pixel electrode PE1, PE2 and PE3, shown in FIG. 2, for example, from an identical material such as ITO or IZO.

The signal wiring line 6 and the pad PD may be disposed both in the same layer. In this case, the signal line 6 and the pad PD may be formed to be separate from or integral with each other. Moreover, as shown, the signal wiring line 6 and pad PD may be disposed in different layers separately, and they may be electrically connected to each other via the contact hole formed in an interlayer insulating film between the signal wiring line 6 and the pad PD.

The ribs 15, the sealing layer 41, the adhesive layer GL and the film FL are disposed in a position which overlaps the first support substrate SP1 along the third direction Z, and they do not extend up to a position overlapping the groove portion GR. The sealing layer 41 covers the ribs 15 and also is in contact with the fourth insulating film 14. The adhesive layer GL covers the sealing layer 41 and also in contact with the fourth insulating film 14.

The wiring substrate FPC1 is mounted in the display panel PNL above the fourth insulating film 14. The wiring substrate FPC1 comprises a core substrate 200, a connection wiring line 100 disposed on an lower surface side of the core substrate 200, and a drive IC chip 3 disposed on an upper surface side of the core substrate 200. The driver IC chip 3 functions as, for example, a signal supplier which supplies a signal necessary to drive the display panel PNL thereto. The position of the drive IC chip 3 is not particularly limited, but may be disposed on a lower surface side of the core substrate 200.

The display panel PNL and the wiring substrate FPC1 are electrically connected and also adhered to each other via an anisotropic conductive film 8, which is a conductive material. That is, the anisotropic conductive film 8 contains conductive particles dispersed the adhesive. With this configuration, when the wiring substrate FPC1 and the display panel PNL are pressurized along in the third direction Z from upper and lower sides while interposing the anisotropic conductive film 8 therebetween, and heated, they are electrically and physically connected to each other. The anisotropic conductive film 8 is in contact with and electrically connected to the pad PD. Further, the anisotropic conductive film 8 is in contact with and electrically connected to the connection wiring line 100. With this stricture, the connection wiring line 100 is electrically connected to the pad PD and the signal wiring line 6 via the anisotropic conductive film 8.

In the example illustrated, the protective member PT is in contact with the wiring substrate FPC1, the film FL, the adhesive layer GL, etc. Moreover, the protective member PT is in contact with the upper surface of the wiring substrate FPC1 and the upper surface of the film FL. With the protective member PT thus provided, the insulating substrate 10 can be reinforced in terms of thickness between the wiring substrate FPC1 and the film FL. The protective member PT is formed from a resin, for example.

Here, in this embodiment, the display panel PNL includes a first area AR1 including the display area DA, a second area AR2 including a terminal portion T, and a bend area BA (third area AR3) located between the first area AR1 and the second area AR2. The bend area

BA (third area AR3) is equivalent to a region to be bent when the panel is accommodated into the housing of the electronic device or the like. That is, the bend area BA is bent so as to place the wiring substrate FPC1 and the wiring substrate FPC2 below the display panel PNL. At this time, the pad PD is also to be located below the display panel PNL. The bend area BA is located within the non-display area NDA. The signal wiring line 6 and the protective member PT are disposed in the bend area BA.

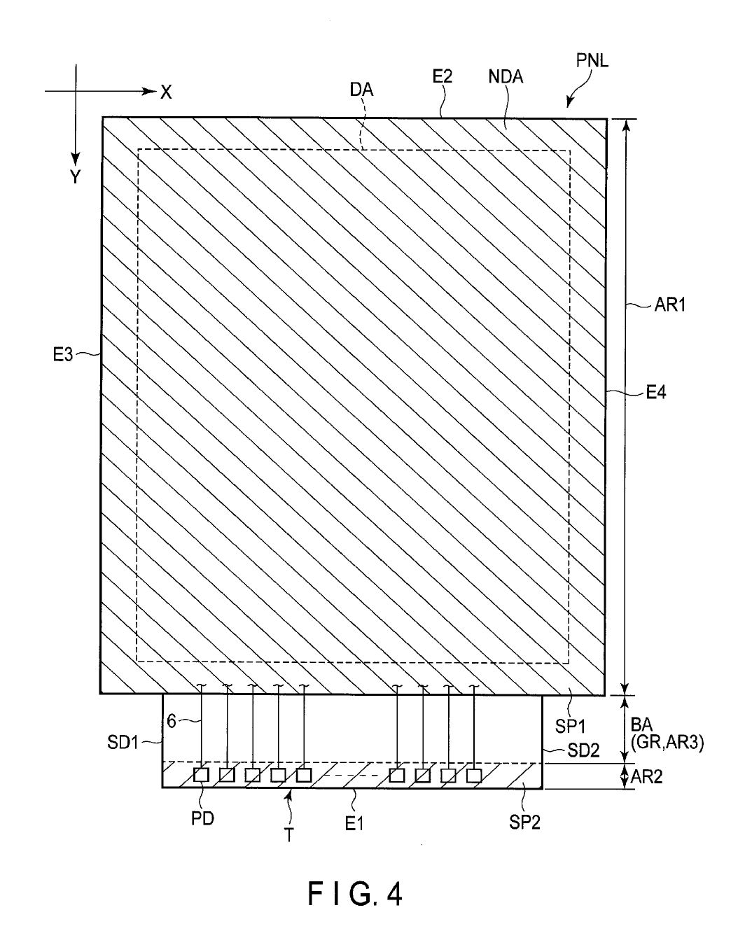

FIG. 4 is a plan view showing the display panel PNL according to this embodiment, which illustrates the positions of the first support substrate SP1 and the second support substrate SP2 and the like, with relative to each other. In FIG. 4, the first support substrate SP1 is indicated by downward-sloping hatch lines, whereas the second support substrate SP2 is indicated by upward-sloping hatch lines.

The display panel PNL comprises a first end portion E1 and a second end portion E2 extending along the first direction X, and a third end portion E3 and a fourth end portion E4 extending along the second direction. The end portion E1 and the end portion E2 oppose each other while interposing the display area DA therebetween. The end portion E3 and the end portion E4 oppose each other while interposing the display area DA therebetween. The first end portion E1 is located on an terminal portion T side, and is formed shorter than the second end portion E2. The display panel PNL includes side portions SD1 and SD2 of the bend area BA.

The first area AR1 overlaps the first support substrate SP1 in plan view. The second area AR2 overlaps the second support substrate SP2 in plan view. A plurality of pads PD are disposed on at the terminal portion T and arranged along the first direction X. The bend portion BA overlaps the groove portion GR in plan view, and extends along the first direction X. That is, in plan view, the bend area BA is located between the first support substrate SP1 and the second support substrate SP2. In other words, in plan view, the bend area BA is located between the display area DA and the terminal portion T. A plurality of signal wiring lines 6 are connected to the pads PD, respectively, and arranged along the first direction X to extend along the second direction Y in the bend area BA. That is, the signal wiring lines 6 extend from the first area AR1 toward the second area AR2. Moreover, as shown in FIG. 4, the bend area BA is formed to have a width along the first direction X less than that of the first area AR1, and therefore it can be easily bent.

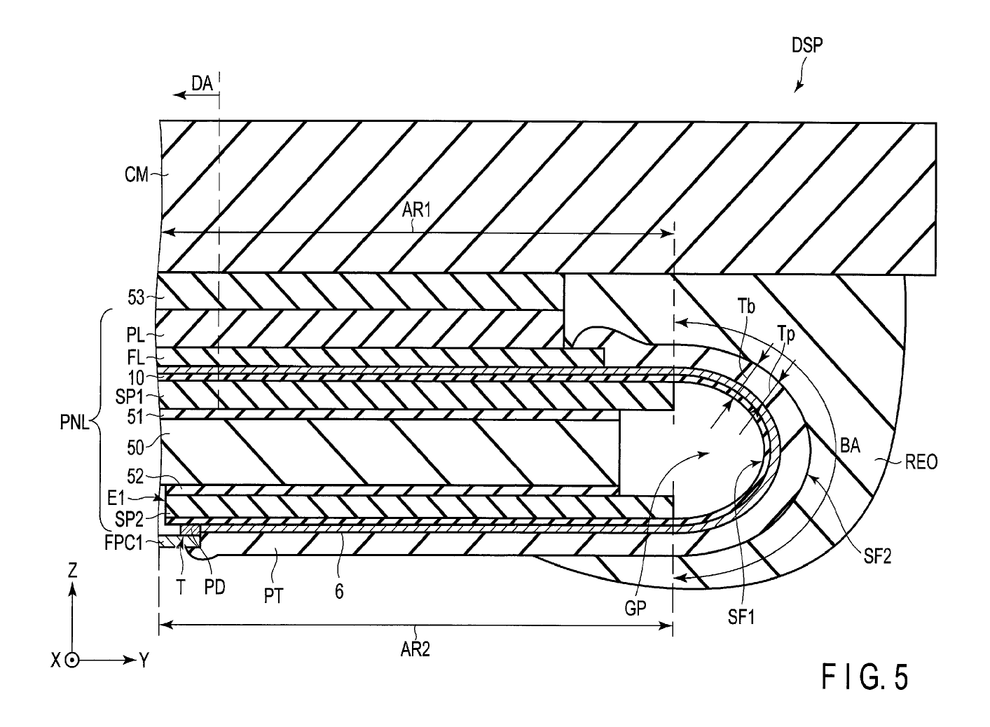

FIG. 5 is a cross section of the bend area BA of the display panel PNL shown in FIG. 3, which has been bent. In FIG. 5, only the main structure of this embodiment is shown and illustration of the other members is omitted.

The display device DSP further comprises a cover member CM, a holding member 50, adhesive layers 51, 52, and 53, an outer resin (first resin) REO and the like. The display panel PNL comprises a polarizer PL located in the first area AR1.

The display panel PNL is bent in the bend area BA so that the first area AR1 and the second area AR2 oppose each other. The second area AR2 is located on an opposite side to the cover member CM with respect to the first area AR1. Further, the bend area BA is bent so that the terminal portion T is located below the display panel PNL. That is, the terminal portion T is located on an opposite side to the cover member CM with respect to the display area DA. Further, the end portion E1 is located on an opposite side to the cover member CM with respect to the display area DA. The signal wiring lines 6 are disposed on the bend area BA, and the protective member PT covers the signal wiring lines 6 in the bend area BA. In the example shown in FIG. 5, a thickness Tp of the protective member PT in the bend area BA is, for example, 80 to 100 μm. Moreover, the bend area BA has a thickness Tb.

The polarizer PL is disposed on the film FL. The cover member CM is disposed on the display panel PNL. The cover member CM is adhered to the polarizer PL via the adhesive layer 53. That is, the cover member CM is adhered to the first area AR1 of the display panel PNL. The cover member CM opposes the display area DA, and extends to a position opposing the bend area BA. The cover member CM is formed of glass, but may be formed from, for example, a material other than glass.

The holding member 50 is disposed between the first support substrate SP1 and the second support substrate SP2. The adhesive layer 51 is disposed between the first support substrate SP1 and the holding member 50 so as to adhere them together. Further, the adhesive layer 52 is disposed between the second support substrate SP2 and the holding member 50 so as to adhere them together. The adhesive layers 51 and 52 are, for example, double-sided tapes.

The outer resin REO covers the bend area BA, externally. In the example illustrated, a gap GP is formed in an inner side of the bend area BA. The outer resin REO is in contact with the protective member PT, the film FL, the polarizer PL, the adhesive layer 53 and the cover member CM. The bend area BA is adhered to the cover member CM by the outer resin REO. As will be described later, the outer resin REO is continuously provided, for example, along the first direction X, so as to cover the entire bend area BA. Note that the outer resin REO should preferably cover at least the positions of the bend area BA, where the wiring lines such as the signal wiring lines 6 and power source wiring lines are provided. Further, between the cover member CM and the outer resin REO, other members such as a decoration film and a touch-panel film may be provided.

The outer resin REO may be formed from the same material as or a different material from that of the protective member PT. Further, the coefficient of elasticity of the outer resin REO is less than or equal to that of the protective member PT, and for example, an impact-absorptive acrylic or silicon material having a low coefficient of elasticity may as well be used therefor. The outer resin REO is formed from, for example, a resin which can be hardened by heat or light. Moreover, as will be described later, the outer resin REO may be formed of a black resin to impart a function as a decoration film provided under the cover member CM.

Here, the insulating substrate 10 comprises a first surface SF1 in the bend area BA. The first surface SF1 is located on an inner side of the bend area BA. Moreover, the protective member PT comprises a second surface SF2 on an opposite side to the first surface SF1 in the bend area BA. The second surface SF2 is located on an outer side of the bend area BA. In the bend area BA, tensile stress and compressive stress are created in the display panel PNL. The tensile stress is maximized in the second surface SF2, and the compressive stress is maximized in the first surface SF1.

When the tensile stress or compressive stress is applied to the members which constitute the display panel PNL, cracking or peeling-off of a member, or breaking of signal wiring lines 6 may occur undesirably. In particular, in the bend area BA, the bending stress produced in the signal wiring line 6 becomes larger, as the radius of curvature becomes smaller, creating possibilities that signal wiring lines 6 may be broken by the shock, the change in temperature or the like. Moreover, the peeling of multilayered films from an interface progresses to the display area DA, thereby causing display errors, or moisture enters from the interface between layers which peeled off from each other, causing the degradation in display performance.

According to this embodiment, the outer resin REO covers the bend area BA. Thus, the bend area BA is reinforced, to inhibit cracking or peeling off of a member, breaking of signal wiring lines 6 and the like in the bend area BA or in its vicinity. Thus, even if the radius of curvature of the bend area BA becomes smaller and the bending stress produced in a member located in the bend area BA becomes heavier, the peeling off and breaking of wiring lines can be suppressed. Moreover, since the entering of moisture from an interface of a multilayer can be suppressed, the peeling-off of a member can be suppressed.

Furthermore, the deformation of the display panel PNL, which may be caused by the repulsive force against the bending stress of the bend area BA, can be suppressed. Thus, the reliability of the display device DSP can be improved.

Next, examples of the above-described embodiment will be described.

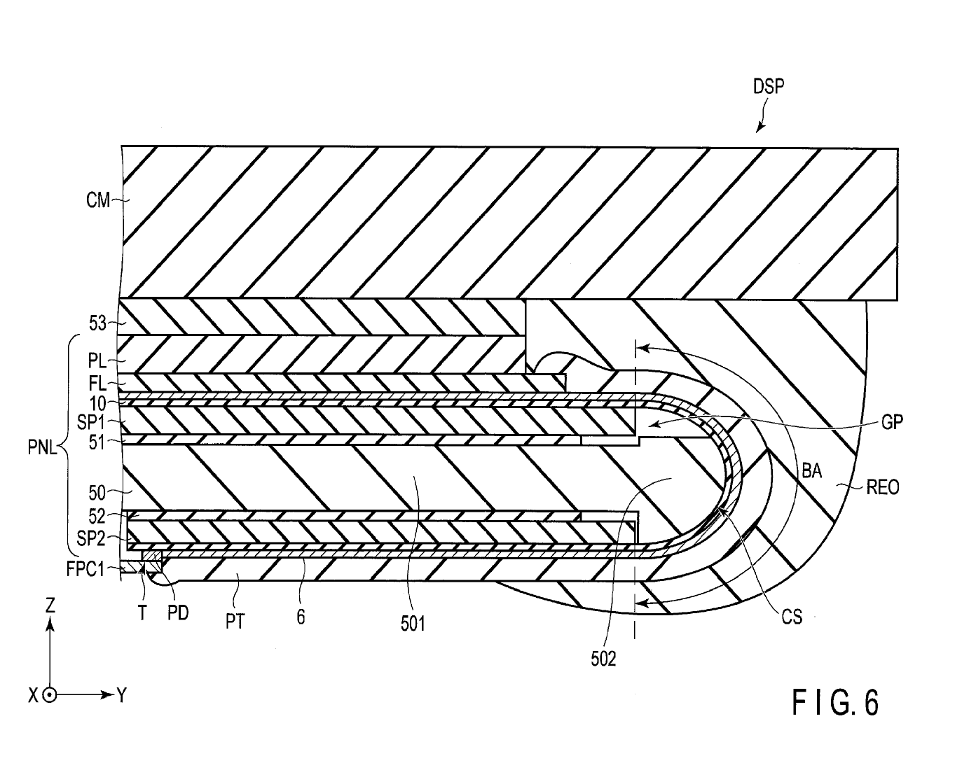

FIG. 6 is a cross-sectional view showing a first example of this embodiment. The structure shown in FIG. 6 is different from that of FIG. 5 in that the holding member 50 is situated in an inner side of the bend area BA.

The holding member 50 comprises a flat plate portion 501 arranged parallel to the X-Y plane and a projection portion 502 extending to the inner side of the bend area BA. The flat plate portion 501 is located between the first support substrate SP1 and the second support substrate SP2. The projection portion 502 is located between the flat plate portion 501 and the bend area BA. The flat plate portion 501 and the projection portion 502 are formed, for example, from an identical material integrally as one body. The projection portion 502 comprises a curved surface CS which is in contact with bend area BA. The bend area BA is bent along the curved surface CS. That is, the radius of curvature of the bend area BA is defined by the projection portion 502. Note that in the inner side of the bend area BA, the space where the projection portion 502 is not placed may be a gap GP. In the example shown in FIG. 6, the gap GP is formed above the projection portion 502 in the inner side of the bend area BA.

In the example also which has such a structure as described, advantageous effects similar to those set forth above can be obtained.

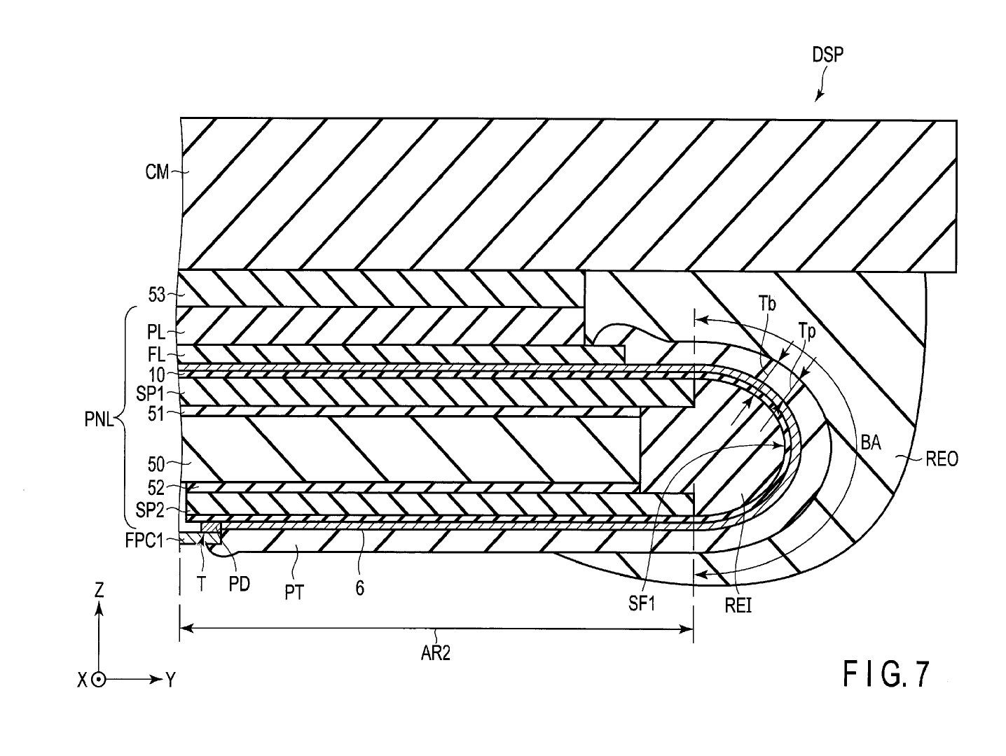

FIG. 7 is a cross-sectional view showing a second example of this embodiment. The structure shown in FIG. 7 is different from that of FIG. 5 in that an inner resin (second resin) REI is situated in an inner side of the bend area BA.

The inner resin REI is in contact with the first surface SF1 of the insulating substrate 10, the first support substrate SP1, the second support substrate SP2, the holding member 50, and the adhesive layers 51 and 52. The inner resin REI is disposed, for example, continuously along the first direction X. The inner resin REI may be formed from a material identical to or different from that of the protective member PT. Moreover, it is preferable that the coefficient of elasticity of the inner resin REI be higher than or equal to, for example, that of the protective member PT. The inner resin REI is formed from, for example, a heat-curable resin.

The inner resin REI may be formed from a material identical to or different from that of the outer resin REO. When the material of the inner resin REI is different from that of the outer resin REO, for example, the coefficient of elasticity of the inner resin REI is higher than that of the outer resin REO. That is, the coefficients of elasticity are set so that the inner resin REI is harder than the outer resin REO and thus the bend area BA is prevented from being dented inward, thereby making it possible to maintain the curvature of the bend area BA. Moreover, the coefficients of elasticity are set so that the outer resin REO is softer than the inner resin REI, and with this configuration, the outer resin REO can easily absorb the shock from the outside of the display device DSP. The coefficient of elasticity of the inner resin REI is 0.1 MPa to 1 GPa, and that of the outer resin REO is 10 KPa to 500 MPa. As shown in FIG. 7, the bend area BA can be reinforced further by covering both the inner and outer sides of the bend area BA by the resins.

When the insulating substrate 10 is a multilayered body of an organic insulating layer and an inorganic insulating layer, the organic insulating layer and the inorganic insulating layer may be peeled off from each other. However, the inner resin REI enters the gap created by the peeling-off, to suppress the spreading of the peeling-off over to the outside of the bend area BA.

The inner resin REI is formed by, for example, filling the inner gap with resin from side portions SD1 and SD2 of the bend area BA shown in FIG. 4. It is preferable that the inner resin REI fills the entire inner side of the bend area BA evenly, but it may contain air bubbles. For example, when filling the gap with the resin from both side portions of the bend area BA, air bubbles may be accumulated near a central portion between the side portions SD1 and SD2. But the air bubbles are sealed by the resin from both sides, and therefore a predetermined pressure can be maintained, making it possible to assure stability. Note that the inner resin REI may be formed by filling the resin from one side of the bend area BA.

In such an example as described above, advantageous effects similar to those described above can be obtained.

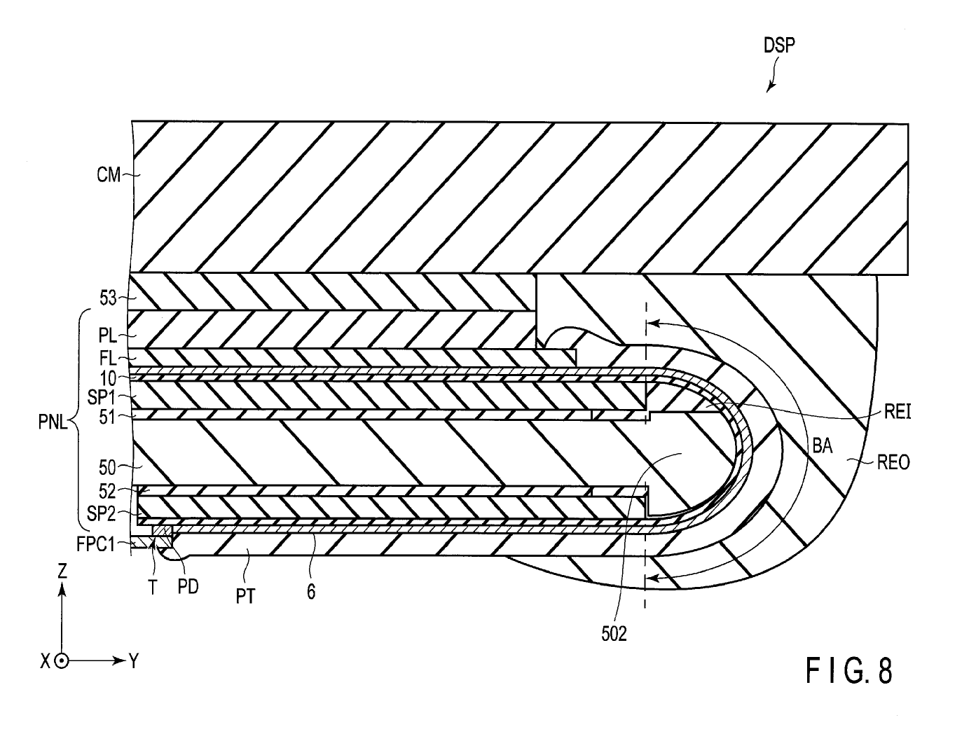

FIG. 8 is a cross-sectional view showing a third example of this embodiment. The structure shown in FIG. 8 is different from that of FIG. 5 in that the inner resin REI and the holding member 50 are located in the inner side of the bend area BA.

As in the case shown in FIG. 6, the projection portion 502 of the holding member 50 is located in the inner side of the bend area BA. The inner resin REI fills the space of the inner side of the bend area BA, where the projection portion 502 is not located.

In such an example as described above, advantageous effects similar to those described above can be obtained.

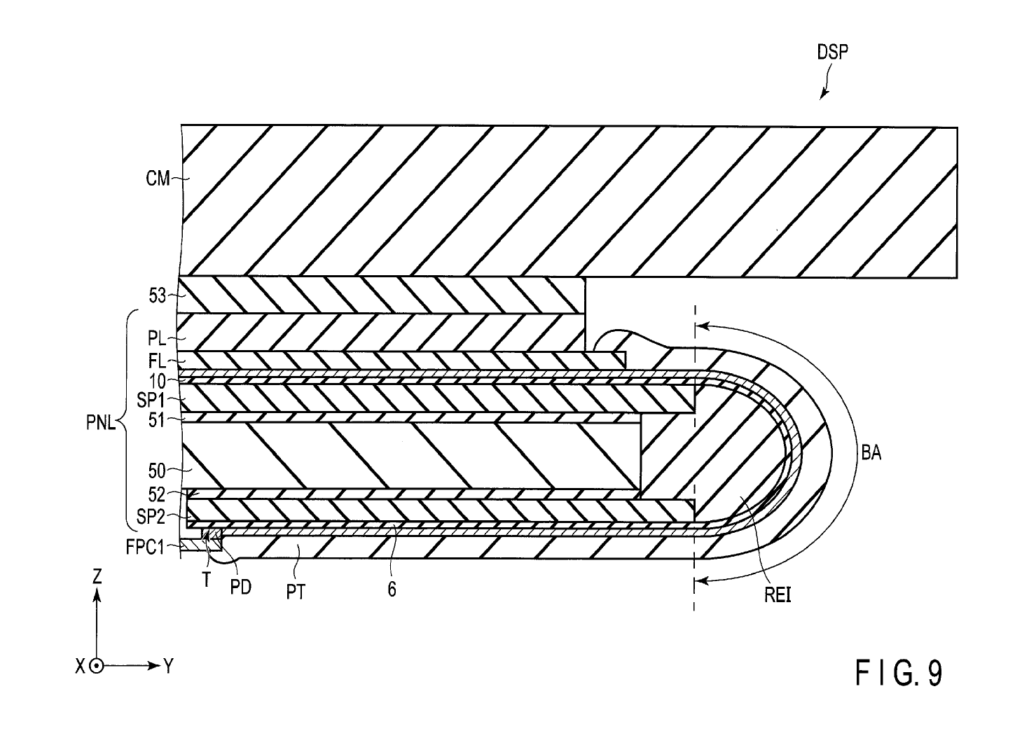

FIG. 9 is a cross-sectional view showing a fourth example of this embodiment. The structure shown in FIG. 9 is different from that of FIG. 5 in that the inner resin REI is located in the inner side of the bend area BA and the outer resin REO is not disposed in the outer side of the bend area BA.

As illustrated, even if the outer resin REO is not provided, the bend area BA can be reinforced by the inner resin REI. Further, with the inner resin REI, the curvature of the bend area BA can be maintained.

In such an example as described above, advantageous effects similar to those described above can be obtained.

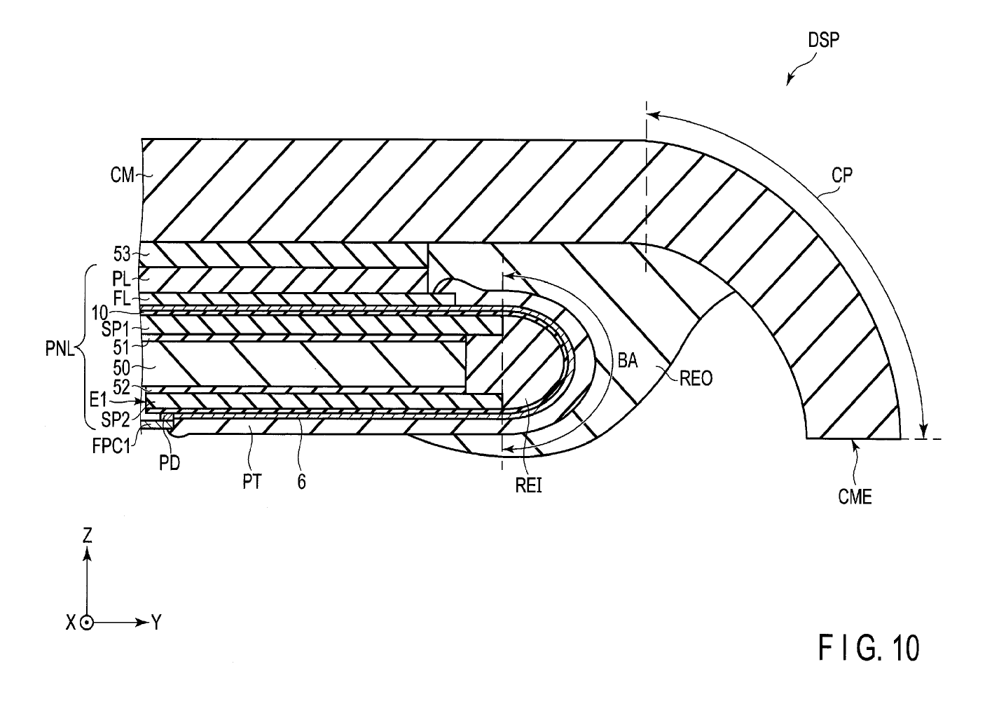

FIG. 10 is a cross-sectional view showing a fifth example of this embodiment. The structure shown in FIG. 10 is different from that of FIG. 7 in that the cover member CM comprises a curved portion (first curved portion) CP.

That is, the cover member CM comprises a curved portion CP on a display panel PNL side in a position corresponding to the bend area BA. The curved portion CP is formed in a position corresponding to the first end portion E1 and the second end portion E2. The cover member CM is curved so that an end portion CME of the cover member CM face downward. The curved portion CP opposes the bent area BA in the second direction Y. The outer resin REO is in contact with the curved portion CP.

In such an example as described above, advantageous effects similar to those described above can be obtained.

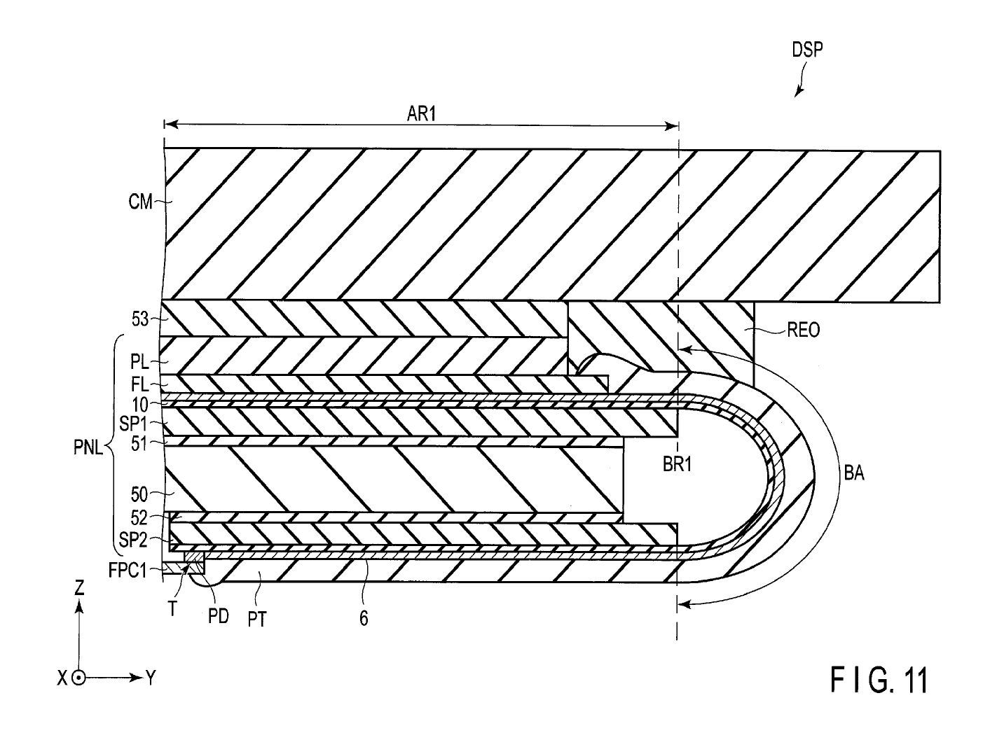

FIG. 11 is a cross-sectional view showing a sixth example of this embodiment. The structure shown in FIG. 11 is different from that of FIG. 5 in that the outer resin REO covers a part of the bent area BA.

A border between the bend area BA and the first area AR1 is defined as a first border BR1. In the first border BR1, a large shearing stress is created in the interface between layers of the multilayer due to the influence of the shearing stress. Consequently, the members located on the first border BR1 are easily peeled off or broken to disconnect. As illustrated, the outer resin REO covers at least the first border BR1, thereby making it possible to suppress the peeling-off or breaking of the members. Moreover, the outer resin REO is disposed between the bend area BA and the cover member CM. With this structure, it is possible to suppress the deformation of the bend area BA upward due to the bending stress.

In such an example as described above, advantageous effects similar to those described above can be obtained.

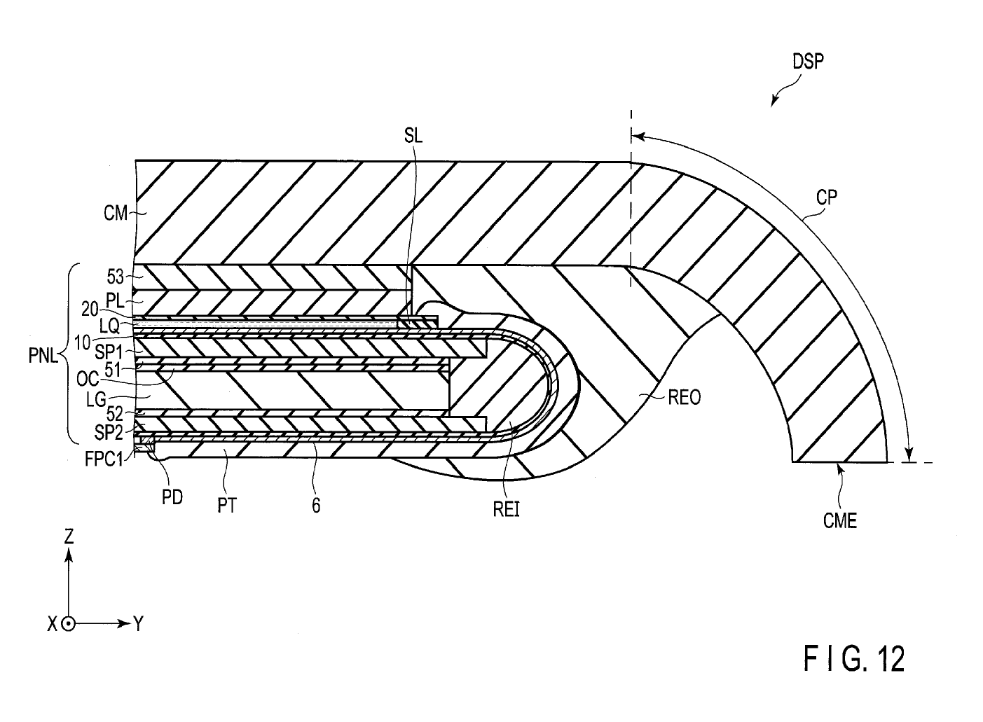

FIG. 12 is a cross-sectional view showing a seventh example of this embodiment. The structure shown in FIG. 11 is different from that of FIG. 5 in that the display device DSP is a liquid crystal display device.

The display panel PNL comprises an insulating substrate 20 disposed on the insulating substrate 10, a liquid crystal layer LQ disposed between the insulating substrate 10 and the insulating substrate 20 and a sealing member SL which seals the liquid crystal layer LQ. When the display panel PNL is a liquid crystal display panel, it may be of a reflective type which displays images by selectively reflecting light entering the display panel PNL from above, or a transmissive type which displays images by selectively transmitting light entering the display panel PNL from below. Note that the main structure of the present embodiment is substantially the same even if the display device DSP is a liquid crystal display device.

The display device DSP comprises a light guide LG and an optical sheet OC between the first support substrate SP1 and the second support substrate SP2. The optical sheet OC is disposed on the light guide LG. The adhesive layer 51 is disposed between the first support substrate SP1 and the optical sheet OC so as to adhere them together. Moreover, the adhesive layer 52 is disposed between the second support substrate SP2 and the light guide LG so as to adhere them together.

In such an example as described above, advantageous effects similar to those described above can be obtained.

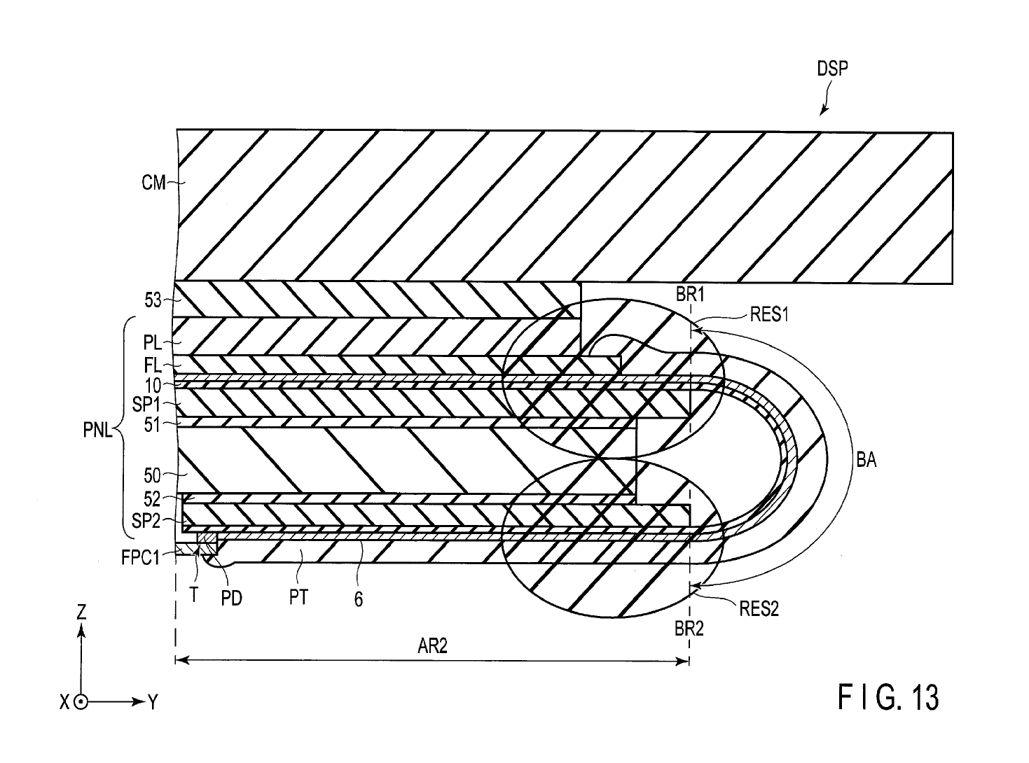

FIG. 13 is a cross-sectional view showing an eighth example of this embodiment. The structure shown in FIG. 13 is different from that of FIG. 5 in that the display device DSP comprises side resins RES1 and RES2. Here, the illustration of the outer resin REO is omitted.

A border on a display area DA side of the bend area BA is defined as a first border BR1, and a border between the bend area BA and the second area AR2 is defined as a second boundary BR2. In the first border BR1 and the second boundary BR2, a large shearing stress is created in the interface between layers of the multilayer due to the influence of the bending stress. When the shearing stress exceeds the adhesive force in the interface between the layers, the peeling-off easily occurs in the interface between the layers. As illustrated, the side resin RES1 covers a portion of the side portions of the bend area BA, which is located on the first border BR1, and the side resin RES2 covers a portion located on the second border BR2. Thus, the peeling off of the members can be suppressed. Note that the side resins RES1 and RES2 are disposed to cover both side portions of the bend area BA as will be described later.

In such an example as described above, advantageous effects similar to those described above can be obtained.

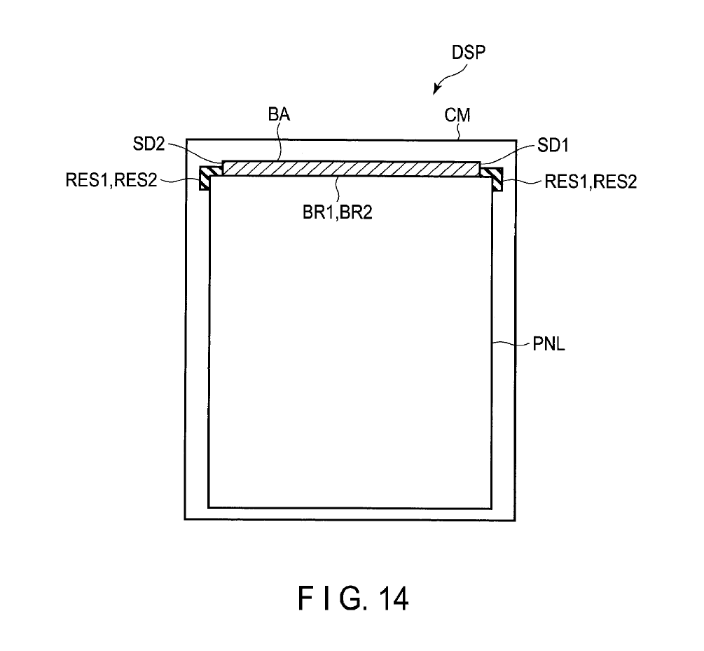

FIG. 14 is a plan view of the display device DSP shown in FIG. 13 as viewed from a cover member CM side. Portions of the side portions SD1 and SD2 of the bend area BA, which are located on both ends of the first border BR1 are covered by the side resin RES1. Portions of the side portions SD1 and SD2 of the bend area BA, which are located on both ends of the second border BR2 are covered by the side resin RES2. Note that the structures shown in FIGS. 13 and 14 may be configured in combination with each of the outer resin REO and the inner resin REI.

In such an example as described above, advantageous effects similar to those described above can be obtained.

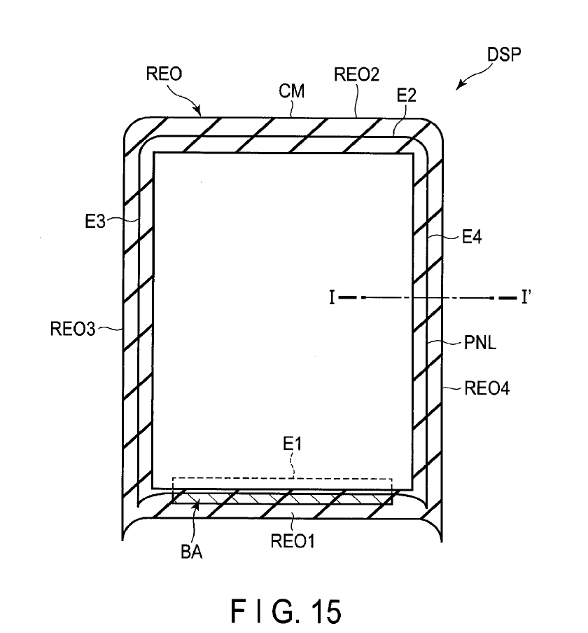

FIG. 15 is a plan view showing a ninth example of this embodiment with respect to the outer resin REO. FIG. 15 shows the case where the end portion E3 and the end portion E4 comprise such a curved surface as shown in FIG. 10.

The outer resin REO includes a first portion REO1 along the end portion E1, a second portion REO2 along the end portion E2, a third portion REO3 along the end portion E3 and a fourth portion REO4 along the end portion E4. As illustrated, the outer resin REO is in contact with the cover member CM, for example, except for the portion in contact with the bend area BA, by at least one of the second end portion E2, the third end portion E3, and the fourth ends E4. For example, the first to fourth portion may be formed from a black resin, so as to function as a substitute for the decoration film. The substitute for the decoration film may be one or more of the first to fourth portions. Of the first to fourth portions, at least one may be formed of a different material from that of the other portions.

In such an example as described above, advantageous effects similar to those described above can be obtained.

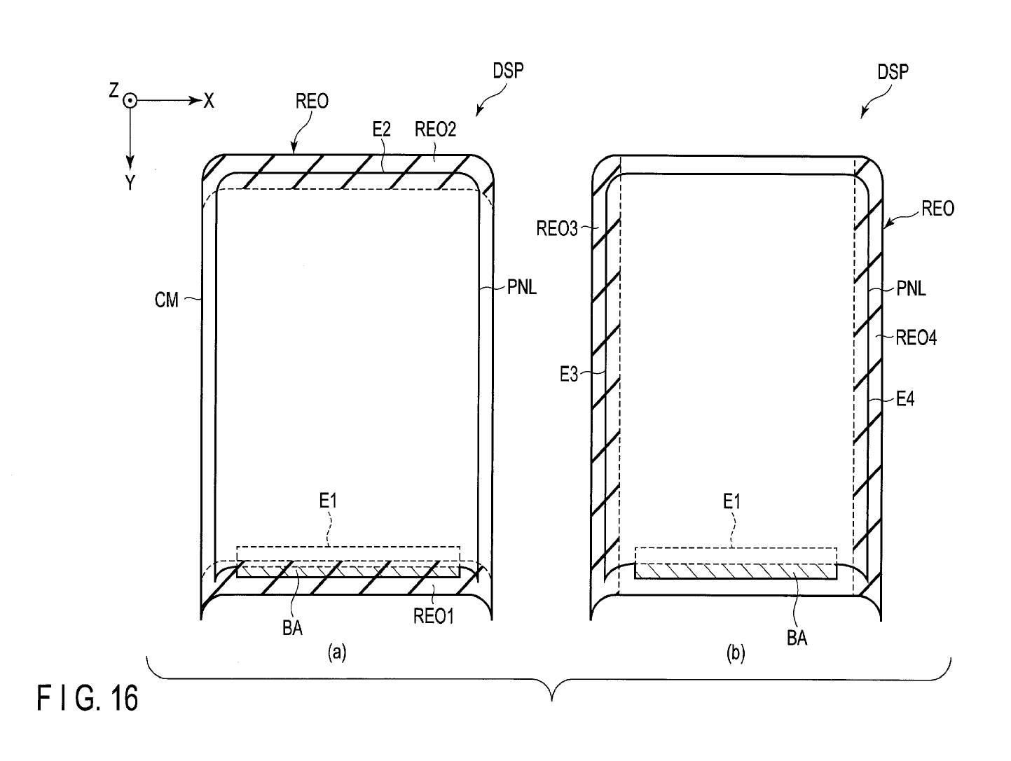

FIG. 16 is a plan view showing a tenth example of this embodiment with respect to the outer resin REO. The structure shown in FIG. 16, part (a) is different from that of FIG. 15 in that only the first portion REO1 and the second portion REO2 are provided. That is, the outer resin REO is disposed along the short ends E1 and E2 of the display panel PNL. The structure shown in FIG. 16, part (b) is different from that of FIG. 15 in that only the third portion REO3 and the fourth portion REO4 are provided. That is, the outer resin REO is disposed along the long ends E3 and E4 of the display panel PNL.

In such an example as described above, advantageous effects similar to those described above can be obtained.

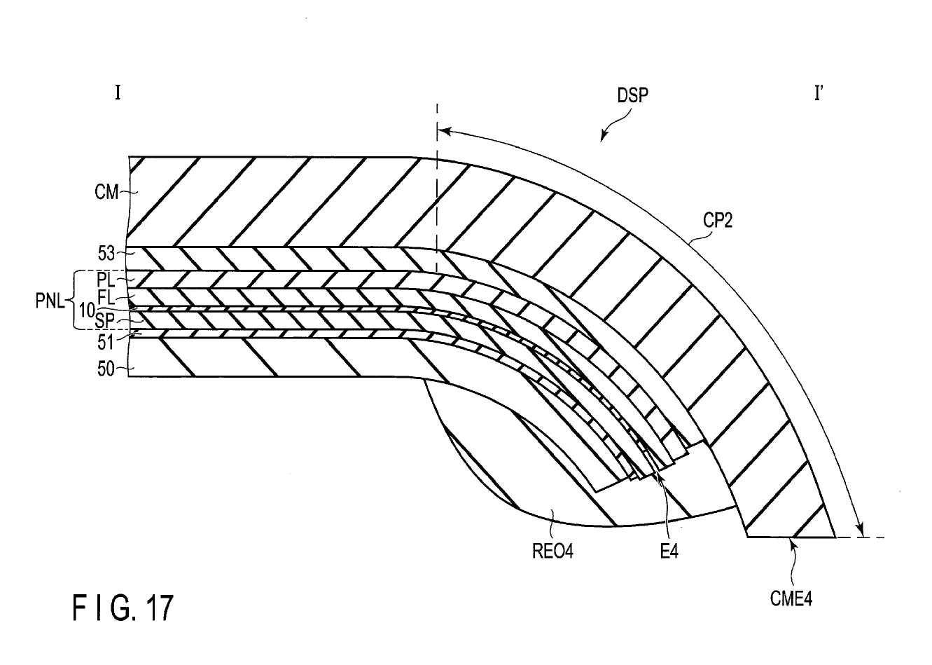

FIG. 17 is a cross-sectional view of the display device DSP shown in FIG. 15, taken along line I-I′.

The cover member CM comprises a curved surface (second curved surface) CP2 curved toward the display panel PNL side. The curved portion CP2 is formed in a position corresponding to the third end portion E3 and the fourth end portion E4. That is, the cover member CM is curved so that the end CME4 thereof faces downward. The display panel PNL extends to a position overlapping the curved portion CP2. In the position overlapping the curved portion CP2, the display panel PNL is curved along the curved portion CP2. The fourth partial (third resin) REO4 is in contact with the curved portion CP2. The fourth portion REO4 covers the end portion E4 so as to fix the display panel PNL and the cover member CM. Thus, the curved portion of the display panel PNL is reinforced, and thus the peeling-off of the members of the display panel PNL and the peeling-off of the display panel PNL from the cover member CM, which may be caused by the bending stress, can be suppressed. Moreover, the entering of moisture, which may be caused by the peeling-off of layers of the display panel PNL from each other, can be suppressed. Further, it is possible to suppress the deformation of the display panel PNL, which may be caused by a repulsive force against the binding.

In such an example as described above, advantageous effects similar to those described above can be obtained.

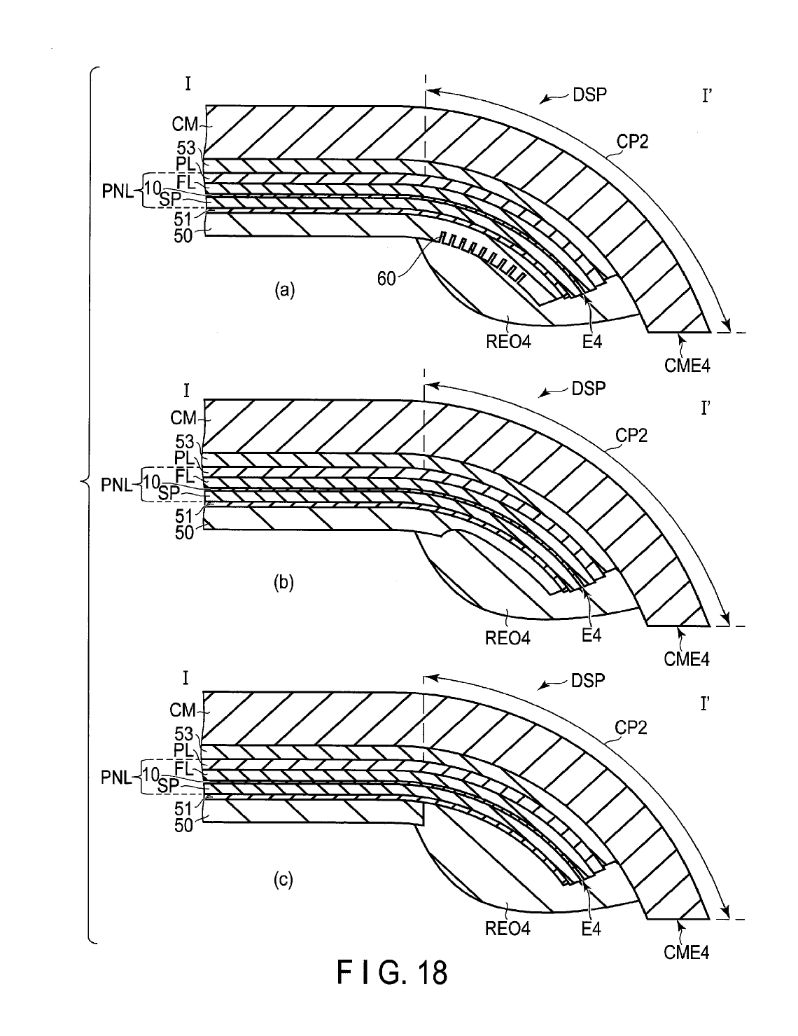

FIG. 18 is a cross-sectional view showing an eleventh example of this embodiment.

The structure shown in FIG. 18, part (a) is different from that of FIG. 17 in that the holding member 50 comprises a cut 60 in a position overlapping the curved portion CP2. The structure shown in FIG. 18, part (b) is different from that of FIG. 17 in that the thickness of the holding member 50 decreases in a position overlapping the curved portion CP2. The structure shown in FIG. 18, part (c) is different from that of FIG. 17 in that the holding member 50 is removed in the position overlapping the curved portion CP2.

According to FIG. 18, parts (a) to (c), in the position overlapping the curved portion CP2, the holding member 50 located furthermost from the cover member CM, where the bending stress is easily applied, can be made easily bended by reducing the bending stress thereto.

In such modified examples as described above, advantageous effects similar to those described above can be obtained.

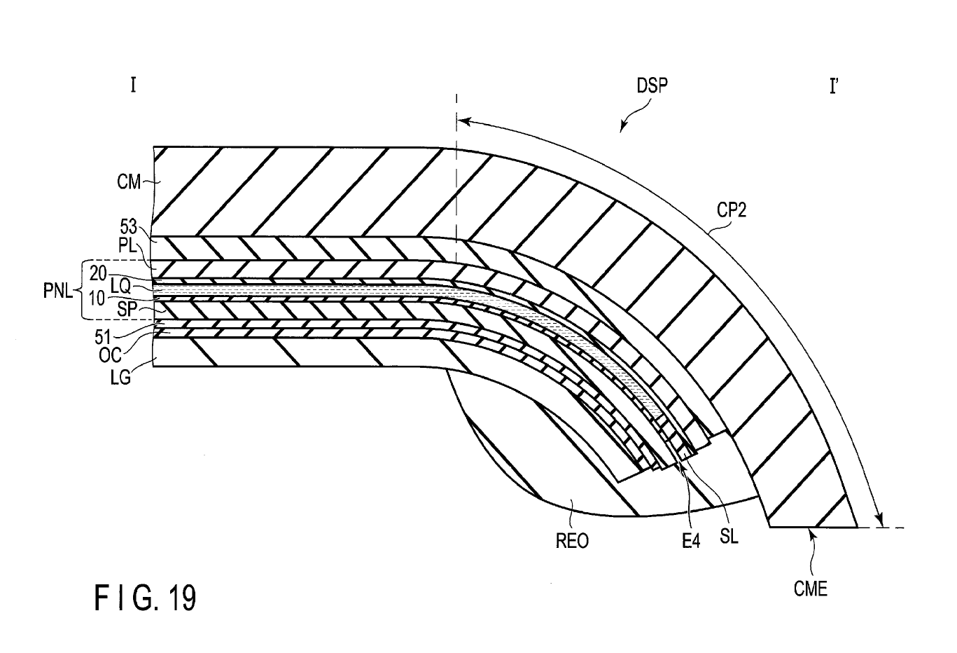

FIG. 19 is a cross-sectional view showing a twelfth example of this embodiment. The structure shown in FIG. 19 is different from that of FIG. 17 in that the display device DSP is a liquid crystal display device. That is, it is different in that a light guide LG and an optical sheet OC are disposed in place of the holding member 50.

The display panel PNL comprises a sealing member SL which seals the liquid crystal layer LQ. The sealing member SL is disposed between the insulating substrate 10 and the insulating substrate 20. The sealing material SL is disposed in a position overlapping the curved portion CP2.

advantageous effects similar to those described above can be obtained.

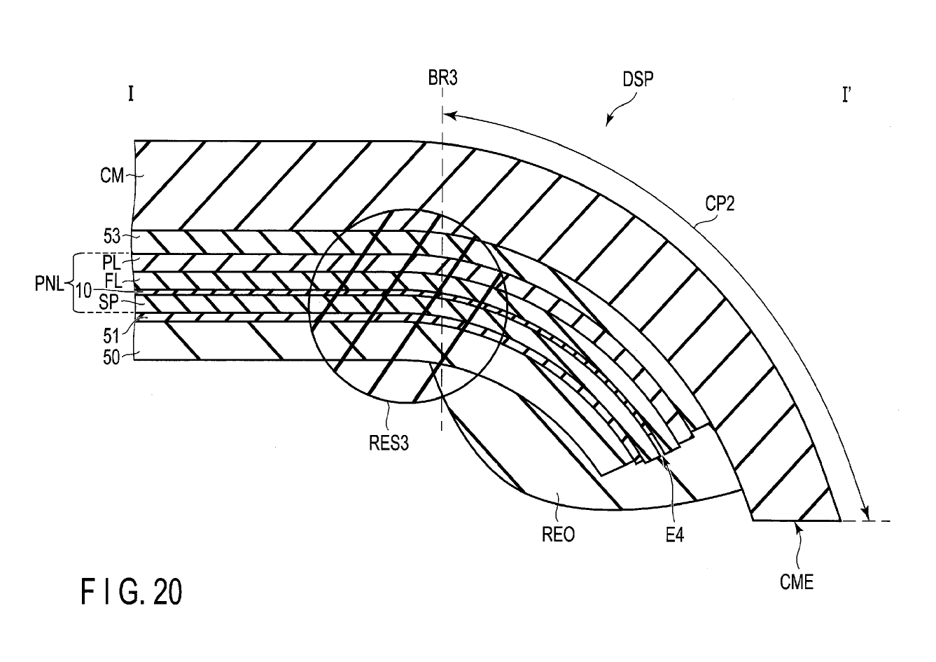

FIG. 20 is a cross-sectional view showing a thirteenth example of this embodiment. The structure shown in FIG. 20 is different from that of FIG. 17 in that the display device DSP comprises a side resin RES3.

The display panel PNL comprises a third border BR3 which is a border between a curved portion and a flat portion. In the third border BR3, a large shearing stress is created in the interface between layers of the multilayer, which may be caused by the influence of the bending stress. As illustrated, the side resin RES3 covers a part of the end of the display panel PNL, which is located above the third border BR3. Thus, the peeling-off of members can be suppressed. Note that the side resin RES3 may be located in both ends of the third border B3.

In such modified examples as described above, advantageous effects similar to those described above can be obtained.

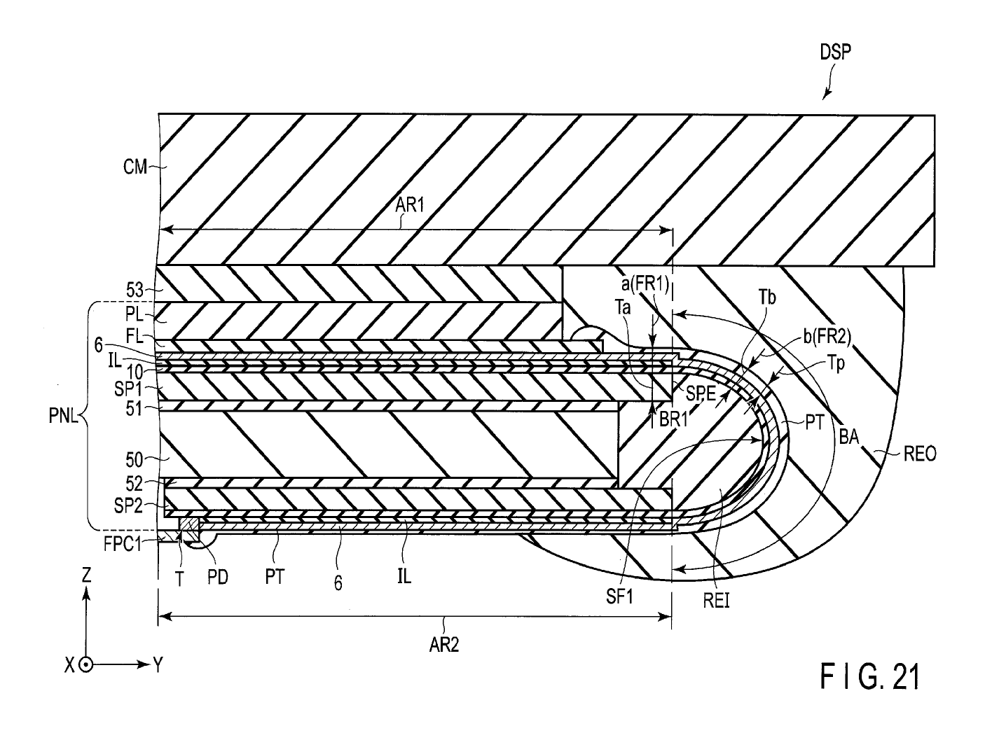

FIG. 21 is a cross-sectional view showing a fourteenth example of this embodiment. The structure shown in FIG. 21 is different from that of FIG. 17 in that the thickness Tp of the protective member PT is less. FIG. 21 illustrates an inorganic insulating film IL. In the example illustrated, the inorganic insulating film IL is not disposed on the bend area BA.

The thickness Tp of the protective member PT should preferably be 60 μm or less in the bend area BA, and more preferably be 50 μm or less. Further, the thickness Tb of the bend area BA is 10 to 60 μm. The thickness Tb of the bend area BA is equal to a sum of the thicknesses of the members located in the bend area BA, and as shown in FIG. 3, for example, the insulating substrate 10, the signal wiring lines 6, the fourth insulating film (organic insulating film) 14 and the protective member PT are stacked one on another in the bend area BA. The thickness Tb shown in FIG. 21 is less than the thickness Tb shown in FIG. 7.

The display panel PNL has a flexural rigidity FR1 in the first position a, and a flexural rigidity FR2 in the second position b. The first position a is located between the first border BR1 and the polarizer PL, and overlaps the first support substrate SP1. The display panel PNL has a thickness Ta in the first position a. The thickness Ta is greater than the thickness Tb. The second position b is located in the bend area BA. The bend area BA should preferably be bent at an end SPE of the first support substrate SP1 as a fulcrum, and bent at the second position b while the first position a is fixed. However, for example, when the flexural rigidities FR1 and FR2 are equal to each other, the bend area BA may be bent from the first position a as it is bent. Then, as the bending stress regionally increases while being bent, the possibility of such a risk that the occurrence of cracks and breaking of lines may increases. Especially, the inorganic insulating film IL is located in the first position a, the signal wiring lines 6 may be broken as the first position a is bent.

According to this embodiment, the protective member PT is formed thin to have a thickness Tp of 60 μm or less, and the bend area BA is formed thin to have a thickness Tb of 10 to 60 μm, and thus the flexural rigidity of the bend area BA can be decreased. With this structure, the bend area BA can be made easily bendable, making it possible to suppress the occurrence of cracks and the breaking of lines, which may be caused by the regional bending stress. Moreover, it is possible to prevent the bind area from being bent from the first position a, and thus the bend area BA can be bent into a desired shape. Then, cracking of the inorganic insulating film IL in the first position a and the breaking of the signal wiring lines 6, which may be caused thereby, can be suppressed.

In the fourteenth embodiment, the bend area BA is bent after the protective member PT having a thickness Tp of 60 μm or less is applied, or it is bent in the state where the protective member PT is not applied, and after that, the protective member PT is applied. Thus, even when the area BA is bent in the state where the protective member PT is not applied, the flexural rigidity is reduced and thus the occurrence of cracking or the breaking of lines and the like can be suppressed as in the cases described above.

Moreover, after the bend area BA is bent, the inner resin REI is formed on an inner side of the bend area BA, and the outer resin REO is formed on an outer side. As in the cases of the examples described above, the inner resin REI and the outer resin REO are formed, and thus the reliability of the display device can be improved. Further, in the fourteenth embodiment, both of the inner resin REI and the outer resin REO are formed, but only one of them may be formed. Note that the fourteenth embodiment may be combined with any one of the embodiments of FIGS. 5 to 20 described above.

Moreover, the thickness Tp of the protective member PT is substantially uniform in the bend area BA and also in the first area AR1 and the second area AR2 on an outer side. Of the protective member PT, only the bend area BA may be formed thin to have a thickness Tp of 60 μm or less.

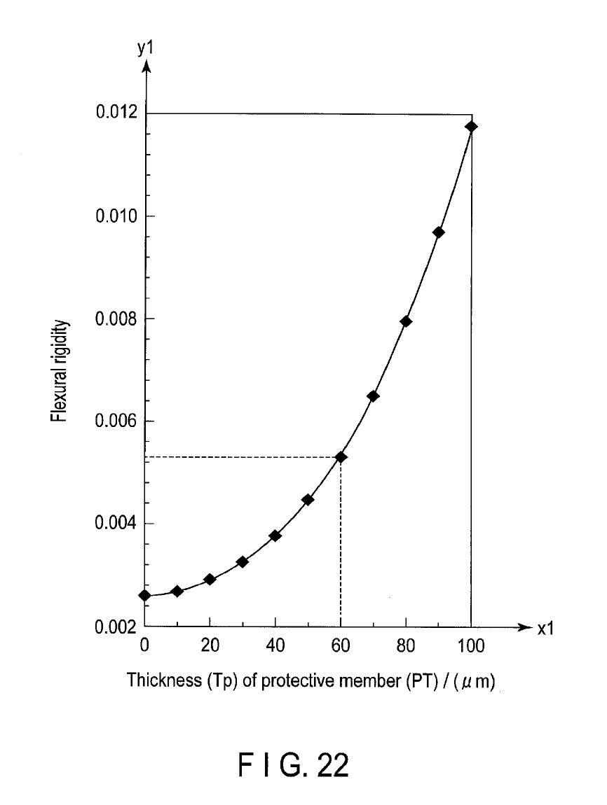

FIG. 22 is a graph illustrating a change in flexural rigidity of the bend area BA with respect to the thickness Tp of the protective member PT. The horizontal axis x1 of the graph indicates the thickness Tp of the protective member PT. The vertical axis y1 of the graph indicates the flexural rigidity of the bend area BA.

The flexural rigidity indicates the difficulty in deformation of the member while being bent, and the bend area BA is more easily bendable as the flexural rigidity is lower. The flexural rigidity is expressed by a product EI of a sectional secondary moment I determined by the sectional shape and size of the member, and the Young's modulus E of the material. The flexural rigidity changes substantially proportionally to the third power of the thickness Tp of the protective member PT as shown in the graph. That is, the flexural rigidity changes greatly against a small change of the thickness Tp. Therefore, as shown in FIG. 21, the flexural rigidity of the bend area BA can be sharply reduced by reducing the thickness of the protective member PT. For example, compared to the cases where the thickness Tp of the protective member PT are 100 μm and 60 μm each other, it is understood that the flexural rigidity is reduced to a half or less.

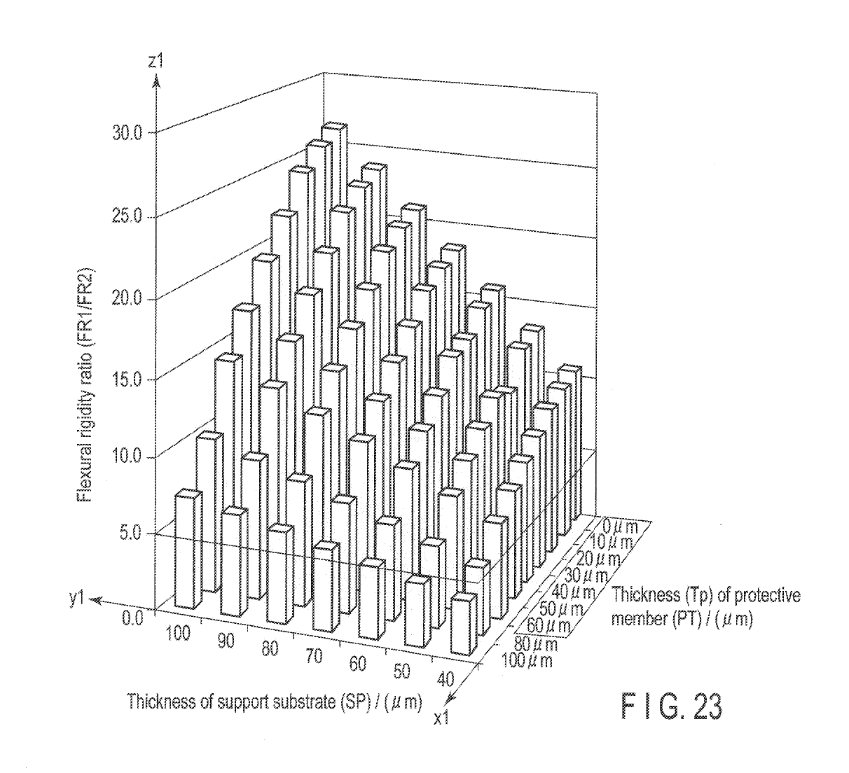

FIG. 23 is a graph showing the ratio between the flexural rigidities FR1/FR2 of the first position a and the second position b with respect to the thickness Tp of the protective member PT and the thickness of the support substrate SP. The horizontal axis x1 indicates the thickness Tp of the protective member PT and the horizontal axis y1 indicates the thickness of the support substrate SP, whereas the vertical axis z1 indicates the ratio between the flexural rigidities FR1/FR2. Here, the flexural rigidity ratio indicates the ratio between the flexural rigidity FR1 of the first position a and the flexural rigidity FR2 of the second position b.

As the flexural rigidity ratio is larger, it becomes more easy to bend the bend area BA while the first position a is fixed. As the flexural rigidity of the first position a is increased by thickening the support substrate SP, and the flexural rigidity of the second position b is decreased by thinning the protective member PT, the flexural rigidity ratio can be increased. For example, when the flexural rigidity ratio is five or higher, the above-described advantageous effect can be obtained. That is, the flexural rigidity FR1 of the first position a is five times or more of the flexural rigidity FR2 of the second position b. As shown in the graph, when the thickness of the support substrate SP is 40 to 100 μm, the flexural rigidity ratio can be maintained to five or more by setting the thickness Tp of the protective member PT to 60 μm or less. Therefore, in the fourteenth embodiment, the thickness Tp of the protective member PT is 60 μm or less.

In such modified examples as described above, advantageous effects similar to those described above can be obtained.

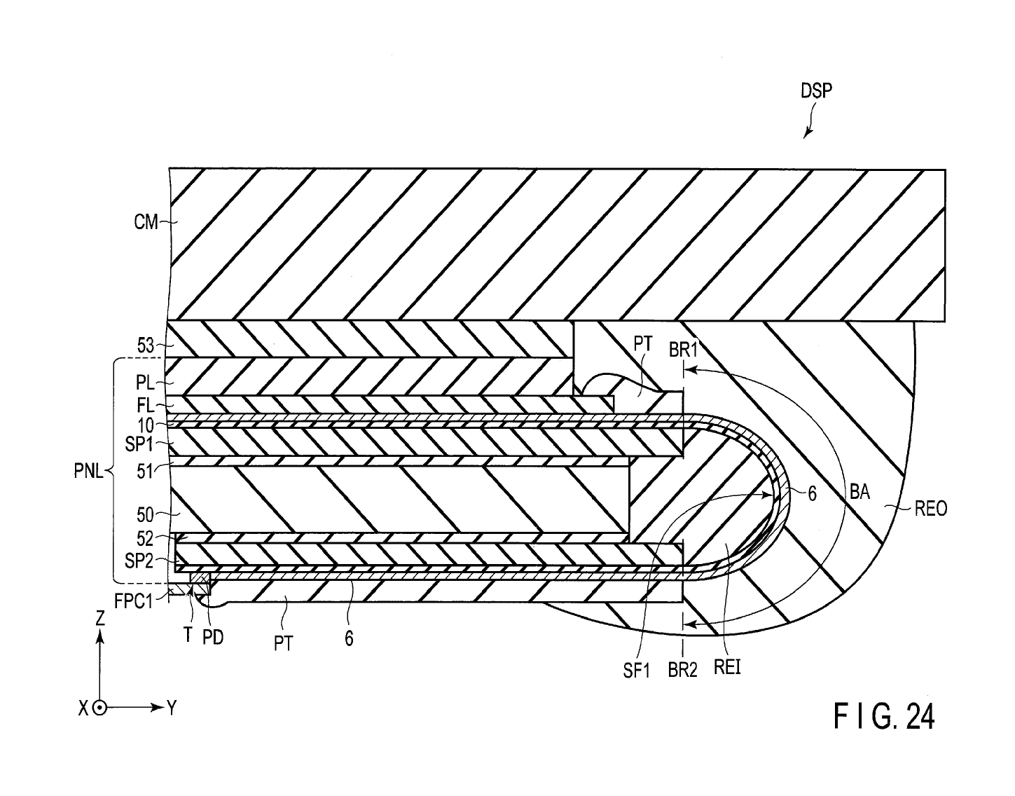

FIG. 24 is a cross-sectional view showing a fifteenth example of this embodiment. The fifteenth example is a modification of the fourteenth example. The structure shown in FIG. 24 is different from that of FIG. 21 in that the protective member PT is not disposed on the bend area BA.

That is, the thickness Tp of the protective member PT is 0 in the bend area BA. Although the protective member PT is disposed not in the bend area BA, but on a polarizer PL side with respect to the first border BR and a pad PD side with respect to the second border BR2. The outer resin REO is in contact with the signal wiring lines 6 in the bend area BA.

In such a modified example as described above, advantageous effects similar to those described above can be obtained.

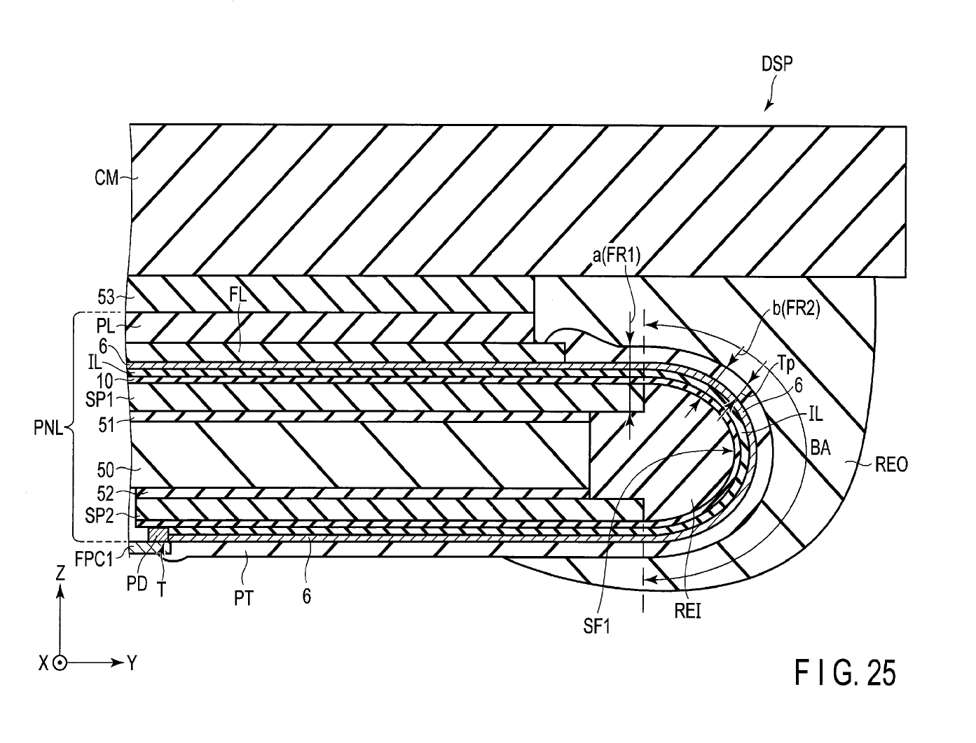

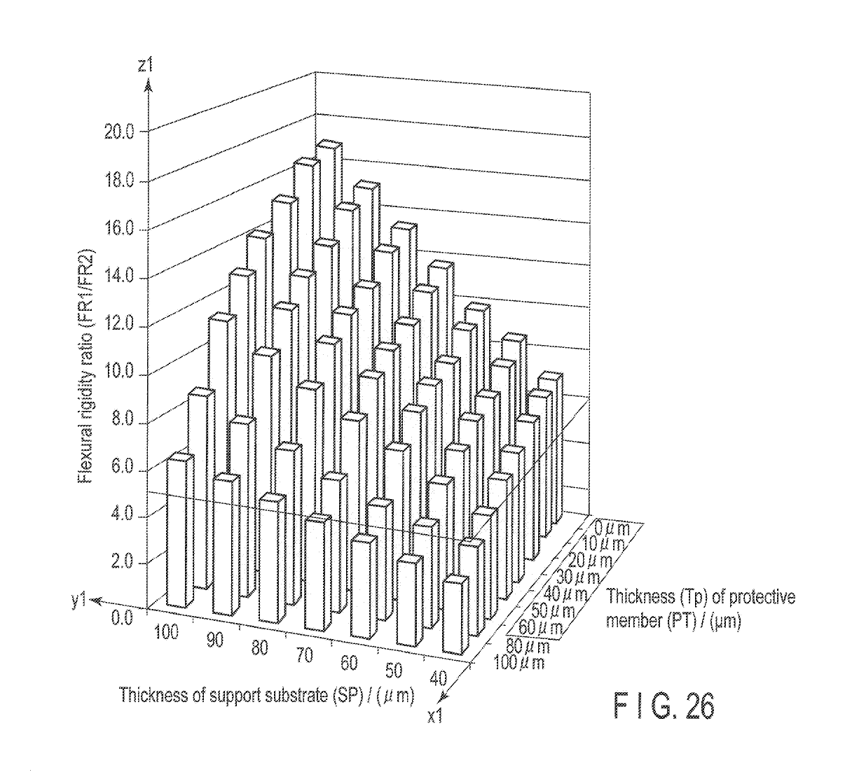

Next, a sixteen embodiment will be described with reference to FIGS. 25 and 26.

FIG. 25 is a cross-sectional view showing the fifteenth example of this embodiment. The sixteenth example is a modification of the fourteenth example. The structure shown in FIG. 25 is different from that of FIG. 21 in that the inorganic insulating film IL is disposed on the bend area BA.

The inorganic insulating film IL is disposed, for example, in a pattern similar to that of the signal wiring lines 6 between the signal wiring line 6 and the insulating substrate 10. Thus, when the inorganic insulating film IL is disposed in the bend area BA, the flexural rigidity FR2 of the second position b increases as compared to the example shown in FIG. 21.

FIG. 26 is a graph showing the flexural rigidity ratio FR1/FR2 between the first position a and the second position b, with respect to the thickness Tp of the protective member PT and the thickness of the support substrate SP in the sixteenth example shown in FIG. 25.

By the inorganic insulating film IL provided in the bend area BA, the flexural rigidity ratio FR1/FR2 is lower as compared to that of the graph shown in FIG. 23. But, when the thickness of the support substrate SP is 40 to 100 μm as in the fourteenth embodiment, the flexural rigidity ratio can be maintained to five or more by setting the thickness Tp of the protective member PT to 60 μm or less. That is, even in the case where the inorganic insulating film IL is located in the bend area BA, it can be stably bent if the thickness Tp of the protective member PT is 60 μm or less.

In such a modified example as described above, advantageous effects similar to those described above can be obtained.

As described above, according to the embodiments, a display device with an improved reliability can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a display panel comprising a first area including a display area, a second area including a terminal portion and a third area located between the first area and the second area; and
a cover member adhered to the first area via an adhesive layer,
the display panel being bent in the third area so that the first area and the second area oppose each other on a side opposite to the cover member, and
the third area being adhered to the cover member by a first resin.

2. The device of claim 1, further comprising:
a second resin located in an inner side of the third area.

3. The device of claim 2, wherein
the first resin and the second resin are formed respectively from materials different from each other.

4. The device of claim 3, wherein
an coefficient of elasticity of the second resin is higher than that of the first resin.

5. The device of claim 1, wherein
the display panel further comprises a wiring line extending from the first area toward the second area in the third area, and a protective member covering the wiring line, and
the first resin is in contact with the protective member.

6. The device of claim 1, wherein
the cover member comprises a first curved surface curved toward the display panel in a position corresponding to the third area.

7. The device of claim 1, wherein
the display panel comprises a first end portion corresponding to the terminal portion and extending along a first direction, a second end portion extending along the first direction, and a third end portion and a fourth end portion, extending along a second direction crossing the first direction, and
at least one of the second end portion, the third end portion and the fourth end portion is adhered to the cover member by a third resin.

8. The device of claim 7, wherein
the cover member comprises a first curved surface curved toward the display panel in a position corresponding to the first end portion and the second end portion.

9. The device of claim 7, wherein
the cover member comprises a second curved surface curved toward the display panel in a position corresponding to the third end portion and the fourth end portion.

10. The device of claim 6, wherein
the third area comprises a first border between the first area and the third area itself, and
a portion of a side surface of the third area, which is located in the first border, is covered by a fourth resin.

11. The device of claim 6, wherein
the third area comprises a second border between the second area and the third area itself, and
a portion of a side surface of the third area, which is located in the second border, is covered by a fifth resin.

12. The device of claim 1, wherein
the first resin covers the entire third area.

13. The device of claim 1, wherein
the display panel further comprises a wiring line extending from the first area toward the second area in the third area, and a protective member covering the wiring line, and
the protective member has a thickness of 60 μm or less in the third area.

14. The device of claim 1, wherein
a thickness of the third area is 10 to 60 μm.

15. The device of claim 14, wherein
an insulating substrate, an wiring line, an organic insulating film and a protective member stacked one on another in the third area.

16. The device of claim 1, wherein
the display panel comprises a first border between the first area and the third area, a polarizer located in the first area, a support substrate overlapping the first area and the second area, a first position overlapping the support substrate between the first border and the polarizer, and a second position of the third area, and
the first position has a flexural rigidity five times or more of that of the second position.

17. The device of claim 13, wherein
the thickness of the protective member is 0 in the third area.

18. The device of claim 17, wherein
the first resin is in contact with the wiring line in the third area.

19. The device of claim 13, wherein
the display panel further comprises an inorganic insulating film in the third area.
